(19) United States
(12) Patent Application Publication
(10) Pub. No.: US 2014/0338748 A1
(43) Pub. Date: Nov. 20, 2014

(54) OPTICAL ELEMENT FOR LIGHT-CONCENTRATING SOLAR POWER GENERATION DEVICE, METHOD FOR PRODUCING SAME, AND LIGHT-CONCENTRATING SOLAR POWER GENERATION DEVICE

(71) Applicant: NIPPON ELECTRIC GLASS CO., LTD., Otsu-shi, Shiga (JP)

(72) Inventors: Takahiro Matano, Otsu-shi (JP); Fumio Sato, Otsu-shi (JP)

(21) Appl. No.: 14/345,266

(22) PCT Filed: Oct. 22, 2012
(86) PCT No.: PCT/JP2012/077195

§ 371 Date: Mar. 17, 2014

(30) Foreign Application Priority Data
Oct. 27, 2011 (JP) 2011-235759
Oct. 19, 2012 (JP) 2012-231352

(51) Int. Cl. H01L 31/0232; H01L 31/052

(52) U.S. Cl. CPC H01L 31/02327; H01L 31/0524
USPC 136/259; 438/69

(57) ABSTRACT

Provided is an optical element for a light-concentrating solar power generation device having excellent weather resistance and also excellent thermal shock resistance and crack resistance, a method for producing the same, and a light-concentrating solar power generation device including the optical element. An optical element for a light-concentrating solar power generation device, the optical element being made of a glass material having a compressive stress at a surface thereof.

### TECHNICAL FIELD

This invention relates to an optical element for use in a light-concentrating solar power generation device, a method for producing the same, and a light-concentrating solar power generation device.

### BACKGROUND ART

In a conventional light-concentrating solar power generation device, an optical element made of glass is provided between a collecting lens and a solar cell. The optical element made of glass has, for example, a prismoidal shape and serves to totally reflect, on the inner surface thereof, light collected by the collecting lens and transmit the light to the solar cell.

The light-concentrating solar power generation device is mainly used outdoors. Therefore, the optical element is required to have excellent weather resistance. For example, Patent Literature 1 discloses that a thin film made of fluorine resin is provided on the side surface of the optical element. Patent Literature 1 proposes a method, based on this structure, for preventing glass components in the optical element from being eluted such as by deposition of water drops on the surface of the optical element to make the element surface cloudy and thus cause leakage of part of light through the clouded surface.

### CITATION LIST

### Patent Literature

Patent Literature 1: JP-A-2006-278581

### SUMMARY OF INVENTION

### Technical Problem

The optical element for use in a light-concentrating solar power generation device is required to have, besides weather resistance, thermal shock resistance and crack resistance. However, in the present situation, conventional optical elements do not achieve these properties to a sufficiently high degree.

With the foregoing in mind, an object of the present invention is to provide an optical element for a light-concentrating solar power generation device having excellent weather resistance and also excellent thermal shock resistance and crack resistance, a method for producing the same, and a light-concentrating solar power generation device including the optical element.

### Solution to Problem

The present invention relates to an optical element for a light-concentrating solar power generation device, the optical element being made of a glass material having a compressive stress at a surface thereof.

Since the surface of the glass material forming the optical element has a compressive stress, the optical element can have excellent mechanical strength and chemical durability. As a result, an optical element excellent in thermal shock resistance and crack resistance can be provided.

Secondly, in the optical element of the present invention, the compressive stress is preferably 1 to 1000 MPa.

Thirdly, the optical element of the present invention preferably has a surface roughness of not more than 200 nm in terms of arithmetic mean roughness (Ra).

With the above structure, the optical reflectance at the surface of the optical element can be increased to improve the efficiency of light gathering to a solar cell. As a result, the power generation efficiency of the solar power generation device can be improved.

Fourthly, in the optical element of the present invention, the glass material preferably has an average coefficient of linear thermal expansion of not more than 120×10⁻⁷/° C. at 30 to 300° C.

With the above structure, an optical element excellent in thermal shock resistance can be easily obtained.

Fifthly, in the optical element of the present invention, the glass material preferably has a Vickers hardness Hv (100) of not less than 500.

The Vickers hardness of the glass material is a property offering an indication of mechanical strength, particularly difficulty of formation of scratches, cracks, chips or the like. If the Vickers hardness falls within the above range, the optical element can be said to be excellent in mechanical strength.

Sixthly, in the optical element of the present invention, when the optical element is subjected to annealing treatment, a density C₁ of the optical element before the annealing and a density C₂ thereof after the annealing preferably satisfy a relationship of (C₁/C₂)×100≦99.9.

The optical element of the present invention has a compressive stress at the surface. This means that the surface has strains. Therefore, the optical element of the present invention has a sparse structure, particularly near the surface, and thus tends to have a small density as compared with an optical element having no compressive stress at the surface (i.e., having no strain). Hence, the ratio C₁/C₂ between the density C₁ of the optical element before the annealing and the density C₂ thereof after the annealing can offer an indication of the degree of compressive stress produced at the surface of the optical element. Specifically, as the compressive stress produced at the surface of the optical element is larger, the value of C₁/C₂ tends to become smaller.

Seventhly, in the optical element of the present invention, the glass material is preferably made of silicate glass.

With the above structure, an optical element having desired properties as described previously can be easily obtained.

Eighthly, the present invention also relates to a method for producing any one of the optical elements described above, wherein a surface of a glass material in a predetermined shape is subjected to a thermal tempering treatment or a chemical tempering treatment to give a compressive stress to the surface.

With the above configuration, the optical element of the present invention can be easily produced.

Ninthly, the present invention relates to a light-concentrating solar power generation device including a solar cell and a collecting optical system configured to collect light to the solar cell, the collecting optical system including any one of the above optical elements.

### Advantageous Effects of Invention

The present invention can provide an optical element for a light-concentrating solar power generation device having excellent weather resistance and also excellent thermal shock resistance and crack resistance.

### BRIEF DESCRIPTION OF DRAWINGS

FIG. 1 is a schematic conceptual view of a light-concentrating solar power generation device according to one embodiment of the present invention.

FIG. 2 is a schematic perspective view of an optical element according to the one embodiment of the present invention.

### DESCRIPTION OF EMBODIMENTS

Hereinafter, a description will be given of an exemplary preferred embodiment for working of the present invention.

However, the following embodiment is simply illustrative. The present invention is not at all limited to the following embodiment.

Throughout the drawings to which the embodiment and the like refer, elements having substantially the same functions will be referred to by the same reference signs. The drawings to which the embodiment and the like refer are schematically illustrated, and the dimensional ratios and the like of objects illustrated in the drawings may be different from those of the actual objects. Different drawings may have different dimensional ratios and the like of the objects. Dimensional ratios and the like of specific objects should be determined in consideration of the following descriptions.

(Light-Concentrating Solar Power Generation Device)

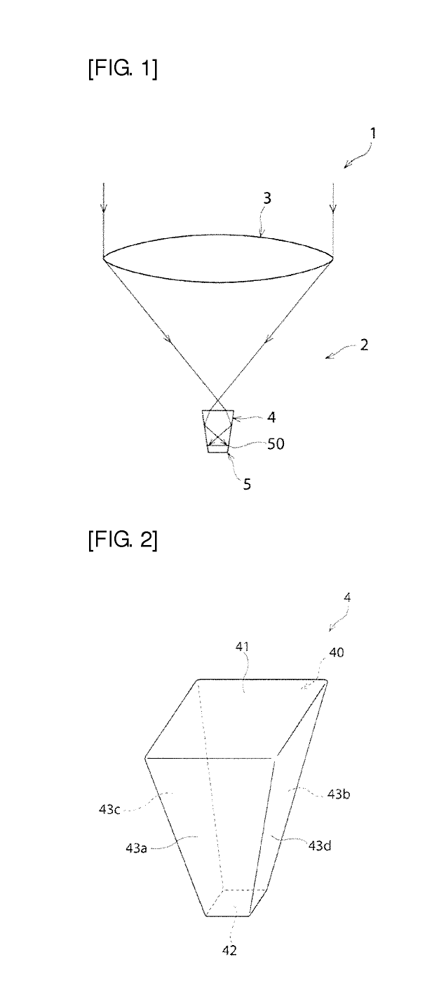

FIG. 1 is a schematic conceptual view of a light-concentrating solar power generation device with an optical element according to this embodiment.

The light-concentrating solar power generation device 1 includes a solar cell 5 and a collecting optical system 2 configured to collect sunlight to the solar cell 5. The collecting optical system 2 includes a light collecting member 3 and an optical element 4. The light collecting member 3 collects light, such as sunlight. The light collecting member 3 can be formed of, for example, a convex lens or a Fresnel lens having a positive optical power.

The optical element 4 is disposed between the light collecting member 3 and the solar cell 5. Light collected by the light collecting member 3 enters the optical element 4 through an end surface 41 (see FIG. 2) of the optical element 4. The optical element 4 homogenizes light collected by the light collecting member 3 and guides the light to an acceptance surface 50 of the solar cell 5. Specifically, light having entered the optical element 4 is reflected at the side surfaces 43a to 43d of the optical element 4 to thereby propagate through the optical element 4 while being homogenized. Then, light having propagated through the optical element 4 is emitted as homogenized flat light through an end surface 42 of the optical element 4 toward the acceptance surface 50.

The solar cell 5 is disposed on the end surface 42 of the optical element 4 with the acceptance surface 50 facing the end surface 42. Light emitted through the end surface 42 of the optical element 4 enters the solar cell 5. Then, in the solar cell 5, optical energy is converted into electrical energy.

No particular limitation is placed on the type of the solar cell 5. The solar cell 5 can be formed of, for example, a single-crystal silicon solar cell, a polycrystalline silicon solar cell, a thin-film solar cell, an amorphous silicon solar cell, a dye-sensitized solar cell or an organic semiconductor solar cell.

(Optical Element)

FIG. 2 is a schematic perspective view of the optical element according to this embodiment. Next, a description will be given of a specific structure of the optical element 4 with reference to FIG. 2.

The optical element 4 has a shape tapering from the side adjacent the light collecting member 3 to the side adjacent the solar cell 5. The surface 40 of the optical element 4 includes: two end surfaces 41, 42 constituting the light entrance and exit surfaces; and side surfaces 43a to 43d constituting light-reflecting surfaces. The end surfaces 41, 42 are opposite to each other. The side surfaces 43a to 43d connect the end surfaces 41, 42.

The optical element 4 is made of a glass material. The glass material forming the optical element 1 preferably contains an alkaline component. Thus, as will be described later, a compressive stress is likely to be produced at the surface of the glass material. Examples of the alkaline component include lithium, sodium, potassium, and cesium.

The glass material is preferably made of silicate glass. Specifically, the glass material preferably contains, for example, 40 to 85% by mass SiO₂, 0 to 30% by mass Al₂O₂, 0 to 30% by mass B₂O₂, 0 to 20% by mass CaO, 0 to 20% by mass MgO, 0 to 20% by mass ZnO, 0 to 20% by mass BaO, 0 to 20% by mass Na₂O, 0 to 20% by mass K₂O, 0 to 20% by mass Li₂O, 0 to 10% by mass TiO₂, 0 to 20% by mass ZrO₂, 0 to 1% by mass Sb₂O₂, and 0 to 20% by mass SrO.

In the present invention, silicate glass includes borosilicate glass.

In the glass material, the average coefficient of linear thermal expansion in a temperature range of 30 to 300° C. is preferably not more than 120×10 ⁻⁷/° C. and particularly preferably not more than 100×10⁻⁷/° C. The reason for this is that if the average coefficient of linear thermal expansion of the glass material is too large, the glass material will be likely to crack by thermal shock.

The internal transmittance of the glass material at a wavelength of 400 nm is preferably not less than 80%/10 mm, more preferably not less than 85%/10 mm, and particularly preferably not less than 87.5%/10 mm.

The surface roughness of the surface 40 is, in terms of arithmetic surface roughness (Ra) defined in JIS B0601, normally preferably not more than 200 nm, more preferably not more than 100 nm, still more preferably not more than 50 nm, even more preferably not more than 20 nm, and particularly preferably not more than 10 nm. Thus, the specular reflectance of light at the surface 40 becomes high, so that the leakage of light to the outside of the optical element 4 can be reduced to increase the optical reflectance. Therefore, the efficiency of light gathering to the solar cell 5 can be improved. As a result, the power generation efficiency of the solar power generation device 1 can be further improved. Examples of away to achieve the above surface roughness include mechanical polishing and flame polishing. In particular, by adopting flame polishing, a smaller surface roughness can be easily achieved and the weather resistance of the optical element 4 can be improved.

Round chamfered portions of the edges and corners of the optical element 4 preferably have the same surface roughness as the surface.

The end surfaces 41, 42 may have antireflection films formed thereon. Thus, upon incidence of sunlight collected by the light collecting member 3 on the optical element 4 and upon incidence of sunlight having transmitted through the optical element 4 on the solar cell 5, light loss by reflection can be reduced. Examples of the antireflection film include a dielectric multilayer film and a silica film. Alternatively, the end surfaces 41, 42 can be given an antireflection function by etching them to form silica-rich layers. A method for forming a silica film and a method for forming a silica-rich layer by etching are less expensive than a method for forming a dielectric multilayer film and therefore can be reduced in cost. The silica film has not only the function as an antireflection film but also the function of reducing the elution of alkaline components contained in the glass material to improve the weather resistance. In addition, by dispersing, for example, fine titanium particles into the silica film, the transmission of ultraviolet rays can be reduced. Thus, for example, when a resin adhesive, such as silicon, is used between the end surface 42 and the acceptance surface 50 of the solar cell 5, the degradation of the resin adhesive due to ultraviolet rays can be reduced.

Furthermore, a reflective coating made such as of Ag, Al, Ni or Cr may be provided on the side surfaces 43a to 43d. Thus, the optical reflectance at the side surfaces 43a to 43d can be further increased. In addition, the side surfaces, the top surface, and the bottom surface may be subjected to water-repellent or hydrophilic treatment for improving the weather resistance.

The surface of the glass material forming the optical element 4 is given a compressive stress.

The compressive stress at the surface 40 of the glass material is preferably 1 to 1000 MPa, more preferably 5 to 900 MPa, still more preferably 10 to 800 MPa, and particularly preferably 10 to 700 MPa. Furthermore, the compressive stress at the surface 40 of the glass material is preferably not less than 50 MPa and more preferably not less than 100 MPa. If the compressive stress at the surface 40 of the glass material is too small, the thermal shock resistance and the crack resistance tend to be poor. On the other hand, if the compressive stress at the surface 40 of the glass material is too large, the glass material will be likely to crack by stress concentration.

The thermal shock resistance of the glass material is preferably not lower than 50° C. and particularly preferably not lower than 60° C. If the thermal shock resistance is too low, the glass material will be likely to crack upon outdoor use, which may cause a reduction in power generation efficiency. The thermal shock resistance refers to a value measured by a method described in Examples to be discussed later.

The Vickers hardness Hv (100) at the surface 40 of the glass material is preferably not less than 500 and particularly preferably not less than 550. If the Vickers hardness is too small, the crack resistance will decrease to result in ease of cracking, which may cause a reduction in power generation efficiency.

The crack resistance at the surface 40 of the glass material is preferably not less than 150 g and particularly preferably not less than 200 g. If the crack resistance is too small, the glass material will be likely to crack, which may cause a reduction in power generation efficiency. The crack resistance refers to a value measured by a method described in Examples to be discussed later.

When the glass material is subjected to annealing treatment, the density C₁ thereof before the annealing and the density C₂ thereof after the annealing preferably satisfy a relationship of (C₁/C₂)×100≦99.9(%), more preferably a relationship of (C₁/C₂)×1009≦9.8(%), and particularly preferably a relationship of (C₁/C₂)×100≦99.7(%). As described previously, as the compressive stress produced at the surface of the optical element is larger, the value of C₁/C₂ tends to become smaller.

In addition, a finding of the inventors showed that when the glass material has a compressive stress at the surface, the output efficiency of light is improved and the power generation efficiency of the solar cell is also improved. The reason for this can be that the glass material having a compressive stress formed at the surface has a structure in which the surface portion is relatively sparse and has a relatively low refractive index and the density and refractive index gradually increase from the surface toward the inside of the glass material, so that the glass material is likely to reflect light at the surface portion and has a high light confinement effect.

The following description is an example of a method for producing the optical element 4.

(Method for Producing Optical Element)

First, a glass material in a predetermined shape is prepared. The glass material can be produced, for example, by a method for directly pressing molten glass, a method for reheat-pressing a glass preform or a method for grinding a glass preform.

Next, the surface 40 of the glass material is given a compressive stress to obtain an optical element 4.

No particular limitation is placed on the method for giving a compressive stress to the surface 40 of the glass material. Examples include a method for molding molten glass and then quenching it (a thermal tempering treatment) and a chemical tempering treatment by ion exchange.

A specific example of the thermal tempering treatment is a method in which a glass material is annealed at a temperature near the glass transition temperature and then cooled at a rate of 10° C./min or above from near the glass annealing point to room temperature (for example, let the glass material cool in room temperature). Alternatively, the glass material may be subjected to mirror finishing by flame polishing at a temperature near the glass softening point and then cooled at a rate of 10° C./min or above from near the glass softening point to room temperature.

A specific example of the chemical tempering treatment is a method in which the glass material is immersed into an alkaline solution at a temperature lower than the glass transition temperature to substitute alkaline ions at the glass material surface with alkaline ions in the alkaline solution.

As thus far described, an optical element 4 is produced by giving a compressive stress to the surface 40 of a glass material. Thus, an optical element 4 excellent in thermal shock resistance and crack resistance can be provided. One reason for this can be that the compressive stress given to the surface 40 of the optical element 4 makes the glass surface difficult to scratch, resulting in reduction in deterioration of thermal shock resistance and crack resistance. It can be also considered as another reason that by previously giving a compressive stress, the difference in stress between the surface and inside of the glass material generated when subjected to external shock can be reduced. Particularly, in the case where the glass material forming the optical element 4 contains an alkaline component, the average coefficient of linear thermal expansion is likely to be relatively large and a compressive stress is likely to form. Therefore, it can be considered that the effect of increasing cracks caused by external shock is more significantly exerted. In the case where the glass material has excellent weather resistance, an origin from which a crack is initiated is less likely to occur. Therefore, the thermal shock resistance and the crack resistance also tend to be high.

The step of giving a compressive stress to the surface 40 of the optical element 4 is preferably performed after the surface is conditioned to have a predetermined surface roughness by mechanical polishing or flame polishing. The reason for this is that if the surface 40 is scratched by polishing after being given a compressive stress, stress will concentrate at the locations of scratches to result in ease of cracking.

In this embodiment, the description has been given of the case where the optical element 4 has a prismoidal shape. However, the present invention is not limited to this structure. In the present invention, no particular limitation is placed on the structure of the optical element so long as it has a shape allowing light collection to the solar cell. Furthermore, the end surfaces may not be flat and may be convex or concave.

### EXAMPLES

The present invention will be described below in further detail with reference to specific examples. However, the present invention is not at all limited to the following examples. Modifications and variations may be appropriately made therein without changing the gist of the invention.

### Example 1

Glass raw materials were prepared to reach a glass composition of, in % by mass, 70% SiO₂, 7% CaO, 2% BaO, 3% ZnO, 12% Na₂O, 5% K₂O, 0.5% TiO₂, and 0.5% Sb₂O₂. These glass raw materials were put into a platinum crucible so that the depth of resultant molten glass reached 50 mm, and the glass raw materials were melted at 1450 to 1650° C. for five hours to obtain molten glass. The molten glass was poured into a heat-resistant mold, pressed into a shape, and then cooled to room temperature while being annealed at a rate of 1° C./min, and the entire surface of the molded body was mechanically polished to obtain a glass material. The obtained glass material had a prismoidal shape in which one end surface was in a square shape with a length of about 10 mm on each side, the other end surface was in a square shape with a length of about 5 mm on each side, and the height was about 20 mm. The average coefficient of linear thermal expansion of this glass material was 97×10⁻⁷/° C. at 30 to 300° C. and the arithmetic surface roughness (Ra) thereof was 2 nm. The glass annealing point (Ta) was 540° C.

The obtained glass material was subjected to a surface tempering treatment to obtain an optical element. Specifically, an optical element was obtained by holding the glass material at 400° C. in an electric furnace for four hours, then taking it out of the electric furnace, and letting it cool in room temperature to give a compressive stress to the surface.

The obtained optical element was measured and evaluated for Vickers hardness, crack resistance, thermal shock resistance, and weather resistance. The results are shown in Table 1.

The measurement and evaluation of the above properties were implemented in the following manners.

[Average Coefficient of Linear Thermal Expansion]

The coefficient of linear thermal expansion was measured in a temperature range of 30 to 380° C. with a dilatometer.

[Arithmetic Surface Roughness (Ra)]

The arithmetic surface roughness was measured with ET4000AK manufactured by Kosaka Laboratory Ltd.

[Surface Compressive Stress]

The surface compressive stress was measured with a surface stress meter (FMS-6000 manufactured by Luceo Co., Ltd.).

[Vickers Hardness]

The Vickers hardness was measured with a hardness tester (MXT50 manufactured by Matsuzawaseiki) in a room held at a temperature of 25° C. and a humidity of 50%. Specifically, a pyramid indenter was pressed against the glass surface at a load of 100 gf for 15 seconds and, based on the length of the diagonal line of a square indentation thus produced on the glass surface, the hardness was evaluated.

[Crack Resistance]

The crack resistance was measured with a hardness tester (MXT50 manufactured by Matsuzawaseiki) in a room held at a temperature of 25° C. and a humidity of 30%. Specifically, a pyramid indenter was pressed against the glass surface at each of loads of 50 gf, 100 gf, 500 gf, and 1000 gf for 15 seconds to produce square indentations on the glass surface. During the indentation production, out of the apexes of the indentations, the number (0 to 4) of apexes at which cracks were formed was measured. The pressure test was conducted 20 times for each load and the incidence of crack was calculated from (the total number of apexes at which cracks were formed)/80 and plotted in a graph. The load at which the incidence of crack reached 50% was found in the obtained graph.

[Thermal Shock Resistance]

The optical elements heated to different temperatures in an electric furnace were immersed in water and the thermal shock resistance was evaluated based on a temperature difference between the temperature in the electric furnace and the water temperature when a crack occurred. It can be said that as the larger the temperature difference, the more excellent the thermal shock resistance.

[Weather Resistance]

The optical element was allowed to stand in a thermo-hygrostat at 85° C. and a relative humidity of 85% for 2000 hours and then the presence/absence of clouding on its surface was observed in a microscope. When neither clouding nor precipitate was found on the surface, the optical element was evaluated to be good (“◯”). When clouding or surface precipitates were found on the surface, the optical element was evaluated to be no good (“×”).

### Example 2

A glass material was obtained in the same manner as in Example 1. The obtained glass material was subjected to a surface tempering treatment to obtain an optical element. Specifically, an optical element was obtained by holding the glass material at 600° C. in an electric furnace for 10 minutes, then taking it out of the electric furnace, and letting it cool in room temperature to give a compressive stress to the surface. The above properties of the obtained optical element were measured in the same manners as in Example 1. The results are shown in Table 1.

### Comparative Example 1

An optical element was obtained in the same manner as in Example 1 except that the surface tempering treatment was not conducted. The obtained optical element was measured for the above properties in the same manners as in Example 1. The results are shown in Table 1.

TABLE 1

| | Ex. 1 | Ex. 2 | Comp. Ex. 1 |
|---|---|---|---|
| Surface Stress (MPa) | 800 | 100 | 0 |
| Vickers Hardness (Hv100) | 650 | 510 | 450 |
| Crack Resistance (gf) | >2000 | 400 | 80 |
| Thermal Shock (° C.) | 90 | 70 | 50 |

### Example 3

Glass raw materials were prepared to reach a glass composition of, in % by mass, 79.5% SiO₂, 2% Al₂O₂, 14% B₂O₃, 4% Na₂O, and 0.5% Sb₂O₂, put into a platinum crucible so that the depth of resultant molten glass reached 50 mm, and melted at 1550 to 1650° C. for five hours. Next, the molten glass was molded in a sheet and cooled to room temperature while being annealed at a rate of 1° C./min, and the resultant sheet was machined to obtain a glass material having the same size as Example 1. The average coefficient of linear thermal expansion of the obtained glass material was 33×10⁻⁷/° C. at 30 to 300° C. and the arithmetic surface roughness (Ra) thereof was 2 nm. The glass annealing point (Ta) was 560° C.

The obtained glass material was subjected to a surface tempering treatment to obtain an optical element. Specifically, an optical element was obtained by holding the glass material at 450° C. in an electric furnace for five hours, then taking it out of the electric furnace, and letting it cool in room temperature to give a compressive stress to the surface.

The obtained optical element was evaluated for the above properties in the same manners as in Example 1. The results are shown in Table 2.

### Comparative Example 2

An optical element was obtained in the same manner as in Example 3 except that the surface tempering treatment was not conducted. The obtained optical element was measured for the above properties in the same manners as in Example 1. The results are shown in Table 2.

TABLE 2

| | Ex. 3 | Comp. Ex. 2 |
|---|---|---|
| Surface Stress (MPa) | 700 | 0 |
| Vickers Hardness (Hv100) | 630 | 450 |
| Crack Resistance (gf) | >2000 | 130 |
| Thermal Shock (° C.) | 120 | 90 |
| Weather Resistance | ∘ | ∘ |

### Example 4

Glass raw materials were prepared to reach a glass composition of, in % by mass, 50% SiO₂, 15% B₂O₃, 14% ZnO, 5% Li₂O, 5% Na₂O, 5% K₂O, 1% ZrO₂, and 5% TiO₂, put into a platinum crucible so that the depth of resultant molten glass reached 50 mm, and melted at 1100 to 1300° C. for three hours. Next, the molten glass was molded in a sheet and cooled to room temperature while being annealed at a rate of 1° C./min, and the resultant sheet was machined to obtain a glass material having the same size as Example 1.

The average coefficient of linear thermal expansion of the obtained glass material was 88×10⁻⁷/° C. at 30 to 300° C. and the arithmetic surface roughness (Ra) thereof was 2 nm. The glass annealing point (Ta) was 480° C.

The obtained glass material was subjected to a surface tempering treatment to obtain an optical element. Specifically, an optical element was obtained by holding the glass material at 380° C. in an electric furnace for three hours, then taking it out of the electric furnace, and letting it cool in room temperature to give a compressive stress to the surface.

The above properties of the obtained optical element were measured in the same manners as in Example 1. The results are shown in Table 3.

### Comparative Example 3

An optical element was obtained in the same manner as in Example 4 except that the surface tempering treatment was not conducted. The obtained optical element was measured for the above properties in the same manners as in Example 1. The results are shown in Table 3.

TABLE 3

| | Ex. 4 | Comp. Ex. 3 |
|---|---|---|
| Surface Stress (MPa) | 650 | 0 |
| Vickers Hardness (Hv100) | 600 | 500 |
| Crack Resistance (gf) | >2000 | 30 |
| Thermal Shock (° C.) | 100 | 60 |
| Weather Resistance | ∘ | ∘ |

### Example 5

Glass raw materials were prepared to reach a glass composition of, in % by mass, 48% SiO₂, 0.5% Al₂O₃, 14% B₂O₃, 13% ZnO, 2.5% Li₂O, 5.5% Na₂O, 7.4% K₂O, 4% ZrO₂, 5% TiO₂, and 0.1% Sb₂O₃, put into a platinum crucible so that the depth of resultant molten glass reached 50 mm, and melted at 1100 to 1300° C. for three hours. Next, the molten glass was molded in a sheet and cooled to room temperature while being annealed at a rate of 1° C./min, and the resultant sheet was machined to obtain a glass material having the same size as Example 1. The average coefficient of linear thermal expansion of the obtained glass material was 86×10⁻⁷/° C. at 30 to 300° C. and the arithmetic surface roughness (Ra) thereof was 2 nm. The glass annealing point (Ta) was 480° C.

The obtained glass material was subjected to a surface tempering treatment to obtain an optical element. Specifically, an optical element was obtained by holding the glass material at 480° C. in an electric furnace for 10 minutes, then taking it out of the electric furnace, and letting it cool in room temperature to give a compressive stress to the surface. The above properties of the obtained optical element were measured in the same manners as in Example 4.

Furthermore, the amount of light emitted from the optical element was measured with a solar simulator as a light source and using a power meter. The obtained amount of light is expressed as a relative value to the value of that in Comparative Example 4 to be described later which is taken as 100.

In addition, the density of the optical element was measured. The optical element was also measured for the density after it was subjected to thermal treatment at 480° C. for 10 minutes and then annealed to room temperature at a cooling rate of 1° C./min. The densities were measured by the Archimedean method.

The results of the above measurements are shown in Table 4.

### Comparative Example 4

An optical element was obtained in the same manner as in Example 5 except that the surface tempering treatment was not conducted. The obtained optical element was measured for the above properties in the same manners as in Example 5. The results are shown in Table 4.

TABLE 4

| | Ex. 5 | Comp. Ex. 4 |
|---|---|---|
| Surface Stress (MPa) | 680 | 0 |
| Vickers Hardness (Hv100) | 600 | 500 |
| Crack Resistance (gf) | >2000 | 30 |
| Thermal Shock (° C.) | 100 | 60 |
| Weather Resistance | ∘ | ∘ |
| Amount of Light | 104 | 100 |
| Density C₁ Before Annealing | 2.728 | 2.744 |
| Density C₂ After Annealing | 2.744 | 2.744 |
| (C₁/C₂) × 100 (%) | 99. 4 | 100 |

As is evident from Tables 1 to 4, the optical elements of Examples 1 to 5, which were given a compressive stress to the surfaces by undergoing the surface tempering treatment, had high Vickers hardness, excellent crack resistance, and excellent thermal shock resistance as compared with the optical elements of Comparative Examples 1 to 4 which had not undergone the surface tempering treatment. Furthermore, it can be seen that the optical element of Example 5 had excellent output efficiency of light as compared with the optical element of Comparative Example 4.

### REFERENCE SIGNS LIST

1. . . light-concentrating solar power generation device

2 . . . collecting optical system

3 . . . light collecting member

4 . . . optical element

40 . . . surface

41, 42 . . . end surface

43a, 43b, 43c, 43d . . . side surface

5 . . . solar cell

50 . . . acceptance surface

1. A An optical element for a light-concentrating solar power generation device, the optical element being made of a glass material having a compressive stress at a surface thereof.

2. The optical element according to claim 1, wherein the compressive stress is 1 to 1000 MPa.

3. The optical element according to claim 1, having a surface roughness of not more than 200 nm in terms of arithmetic mean roughness (Ra).

4. The optical element according to claim 1, wherein the glass material has an average coefficient of linear thermal expansion of not more than 120×10-7/° C. at 30 to 300° C.

5. The optical element according to claim 1, wherein the glass material has a Vickers hardness Hv (100) of not less than 500.

6. The optical element according to claim 1, wherein when the optical element is subjected to annealing treatment, a density C1 of the optical element before the annealing and a density C2 thereof after the annealing satisfy a relationship of (C1/C2)×100≦99.9.

7. The optical element according to claim 1, wherein the glass material is made of silicate glass.

8. A method for producing the optical element according to claim 1, wherein a surface of a glass material in a predetermined shape is subjected to a thermal tempering treatment or a chemical tempering treatment to give a compressive stress to the surface.

9. A light-concentrating solar power generation device including a solar cell and a collecting optical system configured to collect light to the solar cell, the collecting optical system including the optical element according to claim 1.
